(19) United States
(12) Patent Application Publication
(10) Pub. No.: US 2005/0036290 A1
(43) Pub. Date: Feb. 17, 2005

(54) Hatch for an electronic device

(76) Inventors: Kuo-Chang Yang, Taoyuan City (TW); Shih-Hwa Lan, Taipei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/747,716

(22) Filed: Dec. 29, 2003

(30) Foreign Application Priority Data
Aug. 15, 2003 (TW) 92122457

(51) Int. Cl. H05K 7/20

(52) U.S. Cl. 361/704

(57) ABSTRACT

A hatch for an electronic device. The hatch comprises a main body, a thermal insulation layer, a conductive layer and an electrical insulation layer. The thermal insulation layer is disposed on the inner surface of the main body. The conductive layer fully covers the surface of the thermal insulation layer. The electrical insulation layer partially covers the conductive layer and a part of the conductive layer is exposed, wherein heat from the electronic device is insulated by the thermal insulation layer such that the temperature of the surface of the main body is controlled.

### BACKGROUND OF THE INVENTION

1. Field of the Invention

The present invention relates to a hatch for an electronic device, and in particular to a hatch for an electronic device controlling Electromagnetic Interference (EMI), Electrostatic Discharge (ESD), and also external temperature.

2. Description of the Related Art

Conventional electronic devices such as notebook computers normally have housing to protect the electrical components inside. Generally, a housing is provided with a hatch through which components are accessed. As shown in FIG. 1, the housing 1 of a conventional electronic device (such as a notebook computer) has a plurality of protruding pads S on the underside to support the assembly. Particularly, a detachable hatch 2 is attached to the housing 1 by screws 3.

Access to a component (such as a memory device) is enabled by opening the hatch 2. Furthermore, a conductive shielding gasket normally surrounds the hatch 2 providing effective contact with the housing 1 when closed. As the housing 1 is normally made of aluminum-magnesium alloy, EMI from the electrical components inside is also suppressed by the shielding effect of the hatch 2 and the housing 1.

With the progress of semiconductor manufacture and computer technology, the performance and speed of electronic components (such as CPU and memory) is enhanced. Heat generated therefrom, however, also inevitably increases. Thus, the temperature on the underside of the device (especially in the area of the hatch) rises rapidly, to unacceptable levels. As mentioned, while the conventional hatch 2 can suppress EMI, it cannot resolve overheating on the underside of the device, especially the hatch surface.

To address the above-mentioned disadvantages, the present invention provides a hatch for an electronic device that controls Electromagnetic Interference (EMI) and Electrostatic Discharge (ESD), and external temperature.

### SUMMARY OF THE INVENTION

An object of the invention is to provide a hatch for an electronic device. The hatch comprises a main body, a thermal insulation layer, a conductive layer and an electrical insulation layer. The thermal insulation layer is disposed on the inner surface of the main body. The conductive layer fully covers the surface of the thermal insulation layer. The electrical insulation layer partially covers the conductive layer leaving part exposed, allowing heat to be dissipated by the thermal insulation layer such that the temperature on the surface of the main body is stable.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a perspective diagram of a conventional electronic device;

FIG. 2 is a perspective diagram of the hatch in accordance with the present invention;

FIG. 3 an exploded diagram of the hatch in accordance with the present invention; and

FIG. 4 is a large view diagram of A in FIG. 3 in accordance with the present invention.

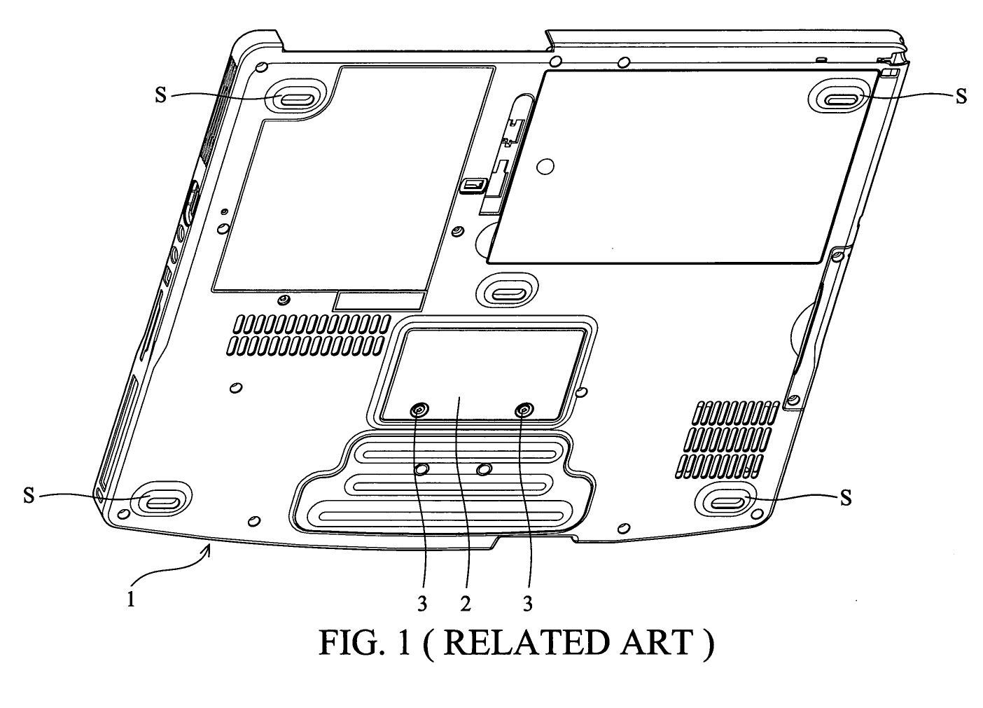

### DETAILED DESCRIPTION OF THE INVENTION

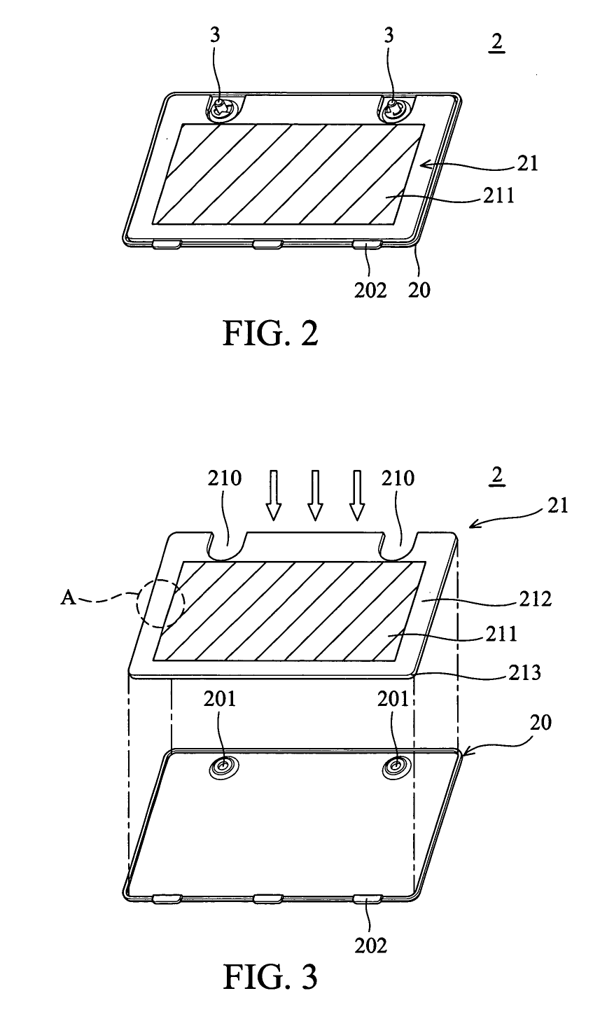

FIG. 2 and FIG. 3 illustrate the hatch of an electronic device in accordance with the present invention. As shown in FIG. 2 and FIG. 3, the hatch 2 comprises a main body 20 and a protecting sheet 21. The main body 20 has two holes 201 through which screws 3 pass into the device. Main body 20 further has a plurality of tabs 202 on its edge, providing firm abutment with the electronic device.

The protecting sheet 21 consists of an electrical insulation layer 211, a conductive layer 212 and thermal insulation layer 213. The thermal insulation layer 213 is disposed on the inner (upper) side of the main body 20 and is made of microcellular PU foams (PORON) material or chloroprene rubber (CR). When heat is transmitted as the arrows indicate in FIG. 3, the thermal insulation layer 213 prevents excessive temperature buildup on the underside of the main body 20.

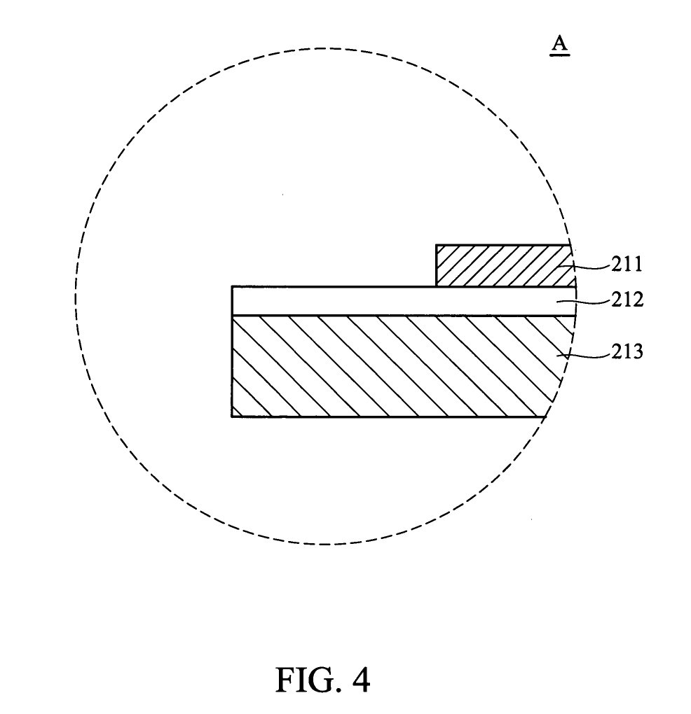

As shown in FIGS. 3 and 4, to suppress EMI and ESD, the conductive layer 212 adheres to the thermal insulation layer 213. The electrical insulation layer 211 does not cover the whole surface of the conductive layer 212 to dissipate heat from the electronic device. The conductive layer 212 is foil of aluminum, copper or other conductive material. When the hatch 2 is attached to the electronic device, the conductive layer 212 forms a shield against EMI and ESD, but also disperses heat uniformly. Thus, excessive temperature buildup is prevented.

As shown in FIG. 4, the conductive layer 212 fully covers the upper surface of the thermal insulation layer 213, with the electrical insulation layer 211 partially disposed on the conductive layer 212. The electrical insulation layer 211 is made of MYLAR or other insulating material, and prevents contact shorts between the electrical components and the conductive layer 212.

In summary, the hatch 2 of the present invention, provided with the protecting sheet 21 controls both Electromagnetic Interference (EMI) and Electrostatic Discharge (ESD), and external temperature. As the microcellular PU foams (PORON) material and chloroprene rubber (CR) are flexible, the conductive layer 212 firmly contacts the housing, forming an effective electrical shield. Moreover, the present invention prevents overheating of the underside of the device, while allowing access to components therein. The constituent layers' adhesion to each other makes it easier and more cost-effective to produce.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. A hatch for an electronic device, comprising:
a main body;
a thermal insulation layer disposed on the inner surface of the main body;
a conductive layer fully covering the surface of the thermal insulation layer;
an electrical insulation layer partially covering the conductive layer, leaving part exposed to dissipate heat from the electronic device.

2. The hatch for an electronic device as claimed in claim 1, wherein the thermal insulation layer is made of microcellular PU foams (PORON).

3. The hatch for an electronic device as claimed in claim 1, wherein the thermal insulation layer is made of chloroprene rubber (CR).

4. The hatch for an electronic device as claimed in claim 1, wherein the conductive layer is aluminum foil.

5. The hatch for an electronic device as claimed in claim 1, wherein the conductive layer is copper foil.

6. The hatch for an electronic device as claimed in claim 1, wherein the electrical insulation layer is made of MYLAR.

7. The hatch for an electronic device as claimed in claim 1, wherein the main body has a hole disposed therein.

8. The hatch for an electronic device as claimed in claim 1, wherein the main body has at least one protrusion on an edge thereof.

9. The hatch for an electronic device as claimed in claim 1, wherein the electronic device is a notebook computer.

10. A notebook computer having a housing and a hatch, comprising:
a main body detachably disposed on the housing;
a thermal insulation layer disposed on a side of the main body, wherein the side is adjacent to heat-generating components;
a conductive layer covering the surface of the thermal insulation layer;
an electrical insulation layer partially covering the conductive layer, leaving part of the conductive layer is exposed and heat from the component is insulated by the thermal insulation layer.

11. The hatch for an electronic device as claimed in claim 10, wherein the thermal insulation layer is made of microcellular PU foams (PORON).

12. The hatch for an electronic device as claimed in claim 10, wherein the thermal insulation layer is made of chloroprene rubber (CR).

13. The hatch for an electronic device as claimed in claim 10, wherein the conductive layer is aluminum foil.

14. The hatch for an electronic device as claimed in claim 10, wherein the conductive layer is copper foil.

15. The hatch for an electronic device as claimed in claim 10, wherein the electrical insulation layer is made of MYLAR.

16. The hatch for an electronic device as claimed in claim 10, wherein the main body has a hole disposed therein.

17. The hatch for an electronic device as claimed in claim 10, wherein the main body has at least one protrusion on an edge thereof.

18. The hatch for an electronic device as claimed in claim 10, wherein the conductive layer is disposed between the electrical insulation layer and the thermal insulation layer.

19. The hatch for an electronic device as claimed in claim 10, wherein the electrical insulation layer is disposed between the component and the conductive layer.
